(19) United States
(12) Patent Application Publication
(10) Pub. No.: US 2010/0085131 A1
(43) Pub. Date: Apr. 8, 2010

(54) FILTER CIRCUIT AND VOLTAGE-CONTROLLED OSCILLATING CIRCUIT

(76) Inventors: Kenji Nakatsuka, Miyagi-Ken (JP); Yasuhiro Ikarashi, Miyagi-Ken (JP)

Correspondence Address: BRINKS HOFER GILSON & LIONE, P.O. BOX 10395, CHICAGO, IL, 60610, US

(21) Appl. No.: 12/572,706

(22) Filed: Oct. 2, 2009

(30) Foreign Application Priority Data
Oct. 6, 2008 (JP) 2008-259799

(51) Int. Cl. H03H 7/46

(52) U.S. Cl. 333/132

(57) ABSTRACT

A filter circuit includes a phase inversion branching circuit branching an input signal and outputting separately first and second signals with mutually-inverted phases from first and second output terminals; a first band rejection filter connected the first output terminal of the phase inversion branching circuit and having a first rejection band; a second band rejection filter connected to the second output terminal of the phase inversion branching circuit and having a second rejection band different from the first rejection band; and a combiner combining the outputs of the first and second band rejection filters.

### CROSS REFERENCE TO RELATED APPLICATION

The present invention contains subject matter related to and claims priority to Japanese Patent Application JP 2008-259799 filed in the Japanese Patent Office on Oct. 6, 2008, the entire contents of which being incorporated herein by reference.

### BACKGROUND

1. Technical Field

The disclosure relates to a filter circuit capable of suppressing undesired signals such as harmonics, which are included in a RF signal output from an oscillator, a wireless receiver and other RF appliances, and to a voltage-controlled oscillating circuit having the filter circuit.

2. Related Art

In the past, there has been an attempt to reduce the harmonics of an oscillation frequency by connecting to a tuning circuit, which tunes a signal to an oscillation frequency, to the output stage of a voltage controlled oscillator. Unfortunately, in such a tuning circuit, stable operation could not be obtained over a wide frequency bandwidth. Further, in order to suppress a spurious signal over a wide bandwidth, a wireless receiver branching high frequency signals to two paths with opposite phases and combining the branched signals has been proposed (see U.S. Pat. No. 6,151,373 “(Patent Document 1”).

In the wireless receiver disclosed in the Patent Document 1, a composite signal is branched to two paths, i.e., a first path and a second path, and at the first path a desired signal is attenuated using a digital notch filter after an AD conversion and the remaining channel signals are inverted. At the second path, the branched signal is delayed by the amount of the first path using a delay circuit. Further, a signal output from the first path and a signal output from the second path are combined with by a coupler so as to lower a level of an undesired signal.

Nonetheless, the filter circuit disclosed in Patent Document 1 requires an A/D converter, which converts the signals of the first path, or a delay circuit, which delays the signal of the second path corresponding to the amount of delay in the first path. Furthermore, the amount of delay in the first path should be matched with the amount of delay in the delay circuit. Thus, if the two amounts of delay do not match, the undesired signals would not cancel out enough.

### SUMMARY

According to an aspect of the disclosure, a filter circuit includes a phase inversion branching circuit, a first band rejection filter, a second band rejection filter, and a combiner. The phase inversion branching circuit branches an input signal and outputs separately a first and second signals with mutually-inverted phases from first and second output terminals. The first band rejection filter is connected to the first output terminal of the phase inversion branching circuit and has a first rejection band. The second band rejection filter is connected to the second output terminal of the phase inversion branching circuit and has a second rejection band different from the first rejection band. The combiner combines the outputs of the first and second band rejection filters.

According to the aspect of the invention, a first rejection band in a first signal mutually phase-inverted by the phase inversion branching circuit is attenuated in the first band rejection filter. A second rejection band in a second signal is attenuated in the second band rejection filter and recombined by the combiner. Thus, since both the first and second signals output from the phase inversion branching circuit passes through the band rejection filter, the delays of the first and second signals can be matched with each other and thereby a signal in which undesired signals were canceled out, other than the first and second rejection bands, can be obtained.

### BRIEF DESCRIPTION OF THE DRAWINGS

FIG. 1 is a diagram illustrating elements of a voltage-controlled oscillating circuit related to an embodiment.

FIG. 2 is a diagram illustrating elements of a first alternative embodiment in which circuit elements after the oscillation circuit unit in the voltage controlled oscillator shown in FIG. 1 are changed.

FIG. 3 is a diagram illustrating the result of simulation in which filter characteristics is simulated depending on the circuit model shown in FIG. 2.

FIG. 4 is a diagram illustrating elements of a second alternative embodiment in which a LC parallel circuit is substituted for the trap circuit shown in FIG. 2.

FIG. 5 is a diagram illustrating the result of simulation in which filter characteristics is simulated depending on the circuit model shown in FIG. 4.

FIG. 6 is a diagram illustrating elements of a third alternative embodiment in which a high-frequency transformer coupler is employed as the output recombining circuit.

FIG. 7 is a diagram illustrating the result of simulation in which filter characteristics is simulated depending on the circuit model shown in FIG. 6.

FIG. 8 is a diagram illustrating elements of a fourth alternative embodiment in which a LC parallel resonance circuit is employed as the trap circuit and a high-frequency transformer coupler is employed as the output recombining circuit.

FIG. 9 is a diagram illustrating the result of simulation in which filter characteristics is simulated depending on the circuit model shown in FIG. 8.

FIG. 10 is a diagram illustrating elements of a comparative example in which a trap circuit is removed from the first signal path and a trap circuit composed of a LC parallel resonance circuit is provided in the second signal path.

FIG. 11 is a diagram illustrating the result of simulation in which filter characteristics of a first comparative example is simulated.

### DESCRIPTION OF EXEMPLARY EMBODIMENTS

Now, exemplary embodiments of the invention will be described in detail herein below with reference to accompanying drawings.

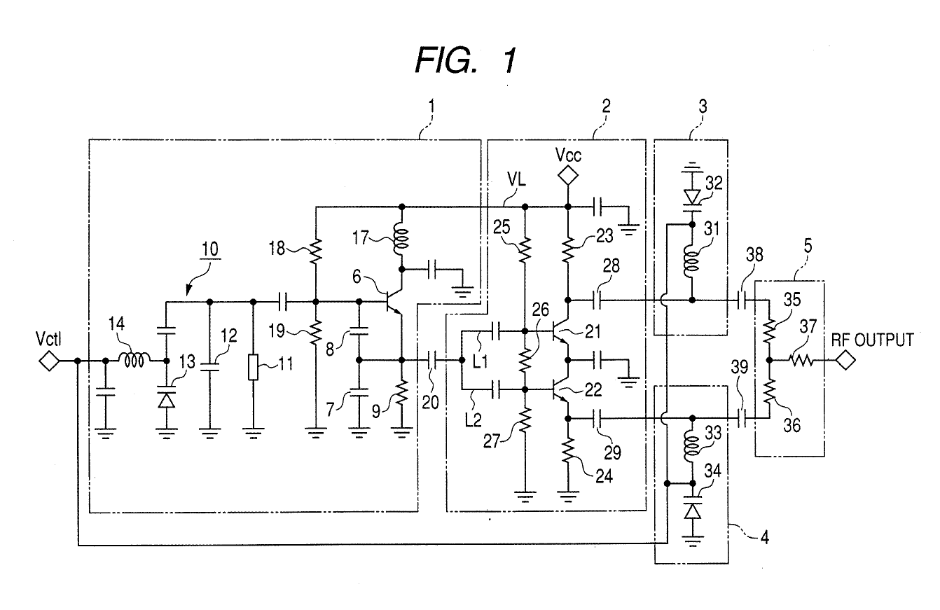

FIG. 1 is a diagram illustrating the elements of a voltage-controlled oscillating circuit related to an embodiment of the invention. A voltage-controlled oscillating circuit of the embodiment includes an oscillation circuit unit 1 having a variable oscillation frequency, an output branching circuit 2 as a phase inversion branching circuit for branching an oscillating signal output from the oscillation circuit unit 1 and mutually inverting the phases, a trap circuit 3 provided in a first signal path on which the one side of the signals output from the output branching circuit 2 propagates, a trap circuit 4 provided in a second signal path on which the other side of the signals output from the output branching circuit 2 propagates and having a different trap frequency from the trap frequency of the trap circuit 3, and an output recombining circuit 5 as a combiner for combining the signals which passed the trap circuits 3 and 4.

The oscillation circuit unit 1 is employed as a collector-grounded Colpitts oscillator circuit, but the invention is not limited to a particular oscillation principle. The collector of the oscillation transistor 6 is grounded in a high-frequency manner, and feedback capacitors 7 and 8 are respectively connected between the base and the emitter, and between the emitter and the collector. The emitter of the oscillation transistor 6 is connected to a connection point of the two feedback capacitors 7 and 8, and is grounded via an emitter bias resistor 9. The base of the oscillation transistor 6 is connected to a resonance circuit 10. The resonance circuit 10 is a parallel resonance circuit in which a striplined inductor 11 and a capacitor 12 are connected parallel to each other. The hot sides of the inductor 11 and the capacitor 12 are connected to the cathode of a varactor diode 13, and a voltage control signal Vctl is applied to the cathode of the varactor diode 13 via a choking coil 14. The hot terminal of the resonance circuit 10 is connected to the base of the oscillation transistor 6. Power source voltage Vcc is applied to a power source line VL, and applied to the collector of the oscillation transistor 6 via a choking coil 17. In addition, dividing resistors 25, 26, and 27 are connected in series between the power source line VL and the ground. The voltage in which the power source voltage Vcc is divided by resistors 18 and 19 is applied to the base of the oscillation transistor 6. The emitter of the oscillation transistor 6 is connected to the input stage of the output branching circuit 2 via a coupling capacitor 20.

The output branching circuit 2 has a first signal path L1 and a second signal path L2, which is branched to form the input stage, so as to form a branching circuit. The end of the first signal path L1 is connected to the base of a phase inversion transistor 21, and the end of the second signal path L2 is connected to the base of a phase inversion transistor 22. In the phase inversion transistor 21 and the phase inversion transistor 22, the emitter of the one phase inversion transistor 21 and the collector of the other phase inversion transistor 22 are cascade-connected to each other. The collector of the one phase inversion transistor 21 is connected to the power source line VL through a resistor 23, and the emitter of the other phase inversion transistor 22 is grounded through a resistor 24. A dividing resistor 25 is connected between the power source line VL and the base of the one phase inversion transistor 21. A dividing resistor 26 is connected between the base of the one phase inversion transistor 21 and the base of the other phase inversion transistor 22. The emitter of the other phase inversion transistor 22 is grounded through a dividing resistor 27. The collector of the one phase inversion transistor 21 is connected to the input stage of the trap circuit 3 via a direct current cutting capacitor 28. The emitter of the other phase inversion transistor 22 is connected to the input stage of the trap circuit 4 via a direct current cutting capacitor 29. The branched in-phase signals are applied to each base of the two phase inversion transistors 21 and 22, but a signal output from the collector of the one phase inversion transistor 21 and a signal output from the emitter of the other phase inversion transistor 22 are mutually phase-inverted. As a result, mutually phase-inverted signals are respectively propagated through the first signal path L1 connected to the collector of the one phase inversion transistor 21 and the second signal path L2 connected to the emitter of the other phase inversion transistor 22.

The trap circuit 3 includes an inductor 31 having one end connected to the first signal path L1, and a varactor diode 32 having a grounded anode and a cathode connected to the other end of the inductor 31. A voltage control signal Vctl applying to the oscillation circuit unit 1 is applied to the cathode of the varactor diode 32. The trap frequency, which is a rejection band of the trap circuit 3, is determined depending on a circuit constant of circuit elements (primarily, inductance of the inductor 31, and capacitance of the varactor diode 32) included in the trap circuit 3. In the trap circuit 3, a frequency almost equivalent to the oscillation frequency of the oscillation circuit unit 1 is established as the trap frequency. The output stage of the trap circuit 3 is connected to the output recombining circuit 5 through a direct current cutting capacitor 38.

The trap circuit 4 includes an inductor 33 having one end connected to the second signal path L2, and a varactor diode 34 having a grounded anode and a cathode connected to the other end of the inductor 33. A voltage control signal Vctl applying to the oscillation circuit unit 1 is applied to the cathode of the varactor diode 34. The trap circuit 4 is similar in elements to the trap circuit 3 provided in the first signal path L1, and both are different from each other only in a trap frequency. That is, since the trap circuit 4 is similar in elements to the trap circuit 3, delay characteristics in the first signal path L1 and the second signal path L2 at a position sufficiently away from the oscillation frequency can be matched with each other. In addition, since the trap frequency of the trap circuit 4 is established at a position deviated from the oscillation frequency (i.e., a position not matched with the harmonics of the oscillation frequency), the oscillation frequency passes through without loss. The output stage of the trap circuit 4 is connected to the output recombining circuit 5 through a direct current cutting capacitor 39.

The output recombining circuit 5 includes a combining resistor 35 having one end connected to the end of the first signal path L1, a combining resistor 36 having one end connected to the end of the second signal path L2 and having the other end connected to the other end of combining resistor 35, and a combining resistor 37 having one end connected to the connection point of the combining resistors 35 and 36. The other end of the combining resistor 37 is the output stage of the output recombining circuit 5.

According to the exemplary embodiment, the resonant frequency in the resonance circuit 10 of the oscillation circuit unit 1 is determined by a voltage control signal Vctl applied to the cathode of the varactor diode 13, and the resonant frequency of the resonance circuit 10 is applied to the base of the oscillation transistor 6. The power source voltage Vcc is divided and applied to the base of the oscillation transistor 6, and the oscillation circuit unit 1 is oscillated based on the oscillation principle of a Colpitts oscillating circuit. As a result, an oscillating signal having an oscillation frequency is supplied from the emitter of the oscillation transistor 6 to the output branching circuit 2 via a coupling capacitor 20.

In the output branching circuit 2, the oscillating signal is branched to a first signal path L1 and a second signal path L2. An oscillating signal branched to the first signal path L1 is applied to the base of the one phase inversion transistor 21. An oscillating signal branched to the second signal path L2 is applied to the base of the other phase inversion transistor 22. In-phase oscillating signals are applied to each base of the phase inversion transistor 21 and 22, which are cascade-connected between the power source line VL and the ground. Mutually phase-inverted oscillating signals are output from the collector of the one phase inversion transistor 21 and the emitter of the other phase inversion transistor 22. As a result, each phase of the harmonics in a signal propagating the first signal path L1 and another signal propagating the second signal path L2 are inverted. Thus, since the transistors 21 and 22 are cascade-connected to the power source, large output amplitude can be obtained. In addition, since the signal passes through only one transistor in the first and second signal paths L1 and L2, an increase of bad effects in the signal caused by an increase in the stage number of transistors can be suppressed.

The oscillating signal output from the collector of the one phase inversion transistor 21, which is in the first signal path L1, is input to the trap circuit 3. In the trap circuit 3, the oscillation frequency of the oscillation circuit unit 1 is established as the rejection band. Thus, a signal in which the oscillation frequency component included in the oscillating signal was attenuated passes through the trap circuit. On the other hand, the oscillating signal output from the emitter of the other phase inversion transistor 22, which is in the second signal path L2, is input to the trap circuit 4. The trap circuit 4 is almost similar in elements to the trap circuit 3 and the amount of delay is established so as to approximately equal to that of the trap circuit 3, but its rejection band is established as a position deviated from the oscillation frequency of the oscillation circuit unit 1. Thus, a signal in which the rejection band deviated from the oscillation frequency was attenuated and the oscillation frequency component was not attenuated is output.

In this case, in the voltage controlled oscillator, the oscillation frequency of the oscillation circuit unit 1 is changed depending on a voltage control signal Vctl. If the oscillation frequency is changed and the trap frequency of the trap circuit 3 is fixed, then the trap frequency is deviated from the oscillation frequency and thereby the oscillation frequency may not be sufficiently attenuated.

According to the exemplary embodiment, the voltage control signal Vctl by which the oscillation frequency of the oscillation circuit unit 1 is controlled is input to the trap circuit 3, the trap frequency is changed depending on the oscillation frequency, and the trap frequency is always matched with the oscillation frequency. In addition, the voltage control signal Vctl is input to the trap circuit 4, the trap frequency is changed depending on the oscillation frequency, and the trap frequency is not matched with the oscillation frequency.

In addition, since the signal which passed the trap circuit 3 and the signal which passed the trap circuit 4 are combined by the output recombining circuit 5 at the post-stage of the trap circuit 3, a signal component attenuated in only one signal path is extracted after the combination without being canceled out. When a narrow trap frequency is established as the oscillation frequency, the oscillation frequency extracted after the combination has a narrow band.

According to the exemplary embodiment, by simply establishing each trap frequency of the trap circuit 3 and the trap circuit 4, a wider oscillation frequency, which is extracted from the output recombining circuit 5, can be obtained. Out of each trap frequency being established in the trap circuit 3 and the trap circuit 4, one trap frequency is deviated from the center oscillation frequency fo to a lower band side by a small amount (−Δ) and the other trap frequency is deviated from the center oscillation frequency fo to a higher band side by a small amount (+Δ). Thus, a wider bandwidth fo−Δ to fo+Δ of the signal, which is extracted from the output recombining circuit 5, can be obtained.

A signal in which the oscillation frequency was attenuated in the trap circuit 3 in the course of propagating the first signal path L1 is input to the output recombining circuit 5 through a resistor 35. A signal in which the oscillation frequency was not attenuated in the trap circuit 4 in the course of propagating the second signal path L2 but the phase is opposite to that of the signal in the first signal path L1 is input to the output recombining circuit 5. When the signal of the first signal path L1 and the signal of the second signal path L2 are combined by combining resistors 35, 36, and 37, then mutually phase-inverted harmonics are canceled out and removed, and an oscillation frequency component not attenuated and included in only the signal of the second signal path L2 is not canceled out and left. As a result, a signal having an oscillation frequency from which a harmonics component was removed is extracted.

In the voltage-controlled oscillator shown in FIG. 1, the branching and the phase inversion are performed separately in the output branching circuit 2, but the branching and the phase inversion may be performed simultaneously using a transformer. In addition, LC series circuits are used as the trap circuit 3 and the trap circuit 4, which are similar in elements to each other, but LC parallel circuits may be used. In addition, as the output recombining circuit 5, the combining resistors 35, 36, and 37 are used, but a transformer may be employed.

### First Alternative Embodiment

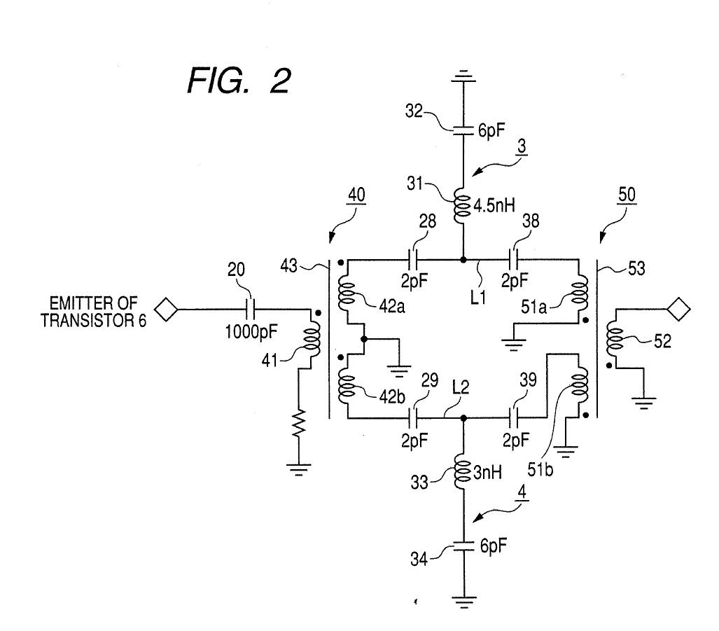

FIG. 2 is a diagram illustrating elements of a first alternative embodiment in which the circuit elements after the oscillation circuit unit 1 in the voltage controlled oscillator shown in FIG. 1 are changed. The trap circuit is similar in elements to that of the above-mentioned embodiment. The oscillation circuit unit 1 is omitted.

In the first alternative embodiment, a high-frequency transformer divider 40, which performs simultaneously the branching and the phase inversion, is installed as the output branching circuit 2 at the pre-stage of a filter unit, and a high-frequency transformer coupler 50 is installed as the output recombining circuit 5 at the post-stage of a filter unit.

The high-frequency transformer divider 40 includes a primary coil 41 having one end connected to the emitter of the oscillation transistor 6 and the other end grounded via a resistor, secondary coils 42a and 42b, and a core 43 magnetically coupling the primary coil with the secondary coils. The one end of the secondary coil 42a is connected to the trap circuit 3 through a direct current cutting capacitor 28, and the one end of the secondary coil 42b is connected to a dummy trap circuit 4 through a direct current cutting capacitor 29. The middle connection point between the secondary coils 42a and 42b is grounded. By grounding the middle connection point between the secondary coils 42a and 42b, a signal extracted from the one end of the secondary coil 42a and a signal extracted from the one end of the secondary coil 42b are mutually inverted in phase. That is, the high-frequency transformer divider 40 enables to perform simultaneously the branching and the phase inversion of the oscillating signal.

The high-frequency transformer coupler 50 includes one first primary coil 51a connected to the end of the first signal path L1, a second primary coil 51b connected to the end of the second signal path L2, a secondary coil 52, and a core 53. In the one primary coil 51a, the one end is connected to a terminal of a direct current cutting capacitor 38, which is one end of the first signal path L1, and the other end is grounded. In the second primary coil 51b, the one end is connected to a terminal of a direct current cutting capacitor 39, which is one end of the second signal path L2, and the other end is grounded. In the secondary coil 52, the one end is an output terminal, and the other end is grounded.

As shown in FIG. 2, for the trap circuit 3, an inductance was set as 4.5 nH, a capacitance 6 pF, and a trap frequency 2.37 GHz with respect to an oscillation frequency of 2.0 GHz. In addition, for the trap circuit 4, an inductance was set as 3.0 nH, a capacitance 6 pF, and a trap frequency 1.94 GHz.

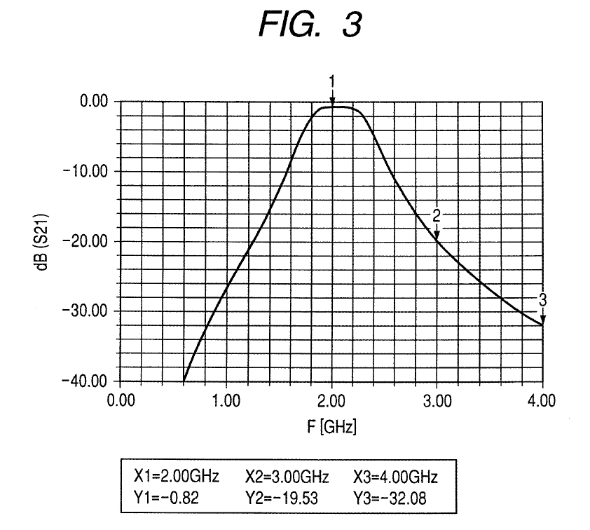

FIG. 3 is a diagram illustrating the result of a simulation in which the filter characteristics were simulated depending on a circuit model shown in FIG. 2 and its circuit constant. As apparent from the result of the simulation, filter characteristics with passband ranging from 1.90 GHz to 2.01 GHz with respect to center oscillation frequency (2.0 GHz) was accomplished. Each trap frequency by the separate trap circuits 3 and 4 described above and the passbands of the combined filter characteristics are respectively different from each other, because the trap circuits 3 and 4 are mutually affected by the other trap circuit.

### Second Alternative Embodiment

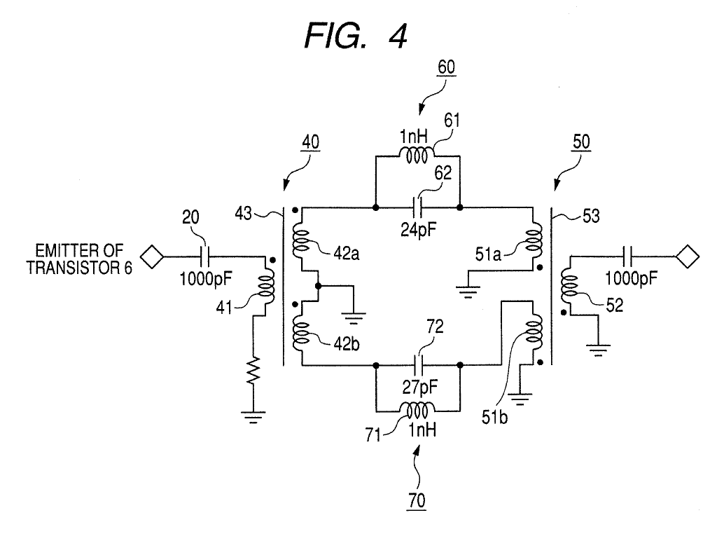

FIG. 4 is a diagram illustrating the elements of a second alternative embodiment in which a LC parallel circuit is substituted for the trap circuit shown in FIG. 2. A trap circuit 60 is a parallel resonance circuit in which an inductor 61 and a capacitor 62 are connected with each other in parallel. A trap circuit 70 is similar in elements to the trap circuit 60, and includes a parallel resonance circuit in which an inductor 71 and a capacitor 72 are connected with each other in parallel.

As shown in FIG. 4, for the trap circuit 60, an inductance was set as 1.0 nH, a capacitance 24 pF, and a trap frequency 1.03 GHz with respect to an oscillation frequency of 1.0 GHz. In addition, for the trap circuit 70, an inductance was set as 1.0 nH, a capacitance 27 pF, and a trap frequency 0.97 GHz.

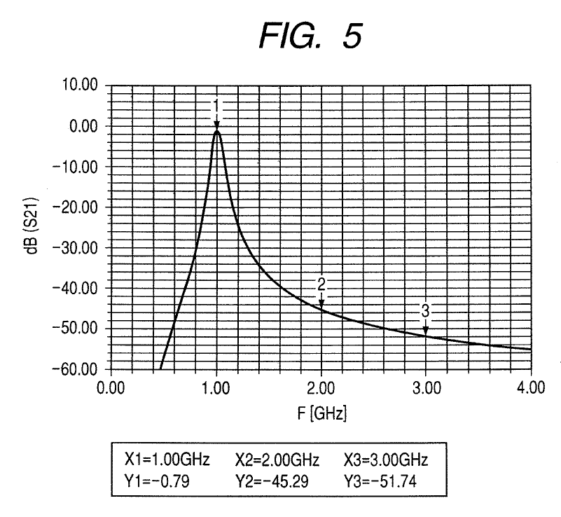

FIG. 5 is a diagram illustrating the result of a simulation in which filter characteristics was simulated depending on a circuit model shown in FIG. 4 and a circuit constant. As apparent from the result of the simulation, a characteristic having very narrow passband with respect to a center oscillation frequency (1.0 GHz) was obtained.

### Third Alternative Embodiment

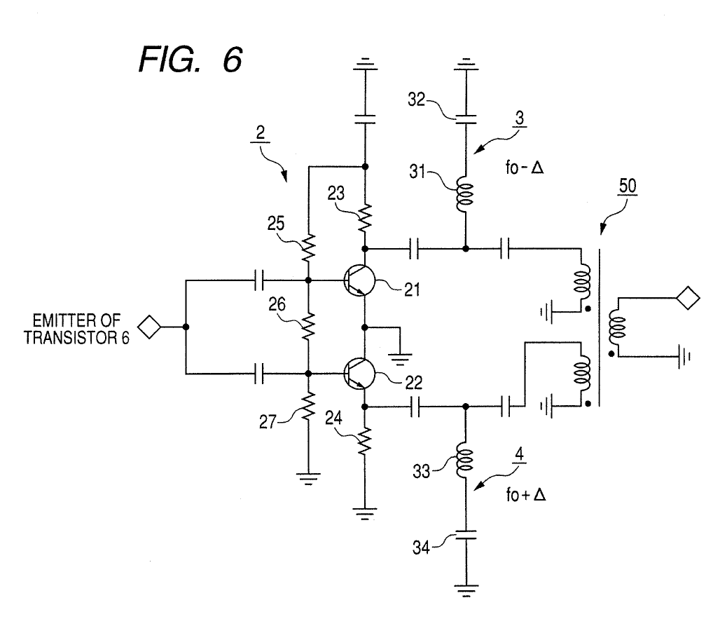

FIG. 6 is a diagram illustrating the elements of a third alternative embodiment, which includes an output branching circuit 2 inverting a phase by using a cascade connection of transistors, trap circuits 3 and 4 composed of LC serial resonance circuits, and a high-frequency transformer coupler 50.

For trap circuit 3, the trap frequency (fo−Δ) deviated from the center oscillation frequency (fo=2.0 GHz) to a lower band side by a small amount is established. In addition, for the trap circuit 4, the trap frequency (fo+Δ) deviated to a higher band side by a small amount is established.

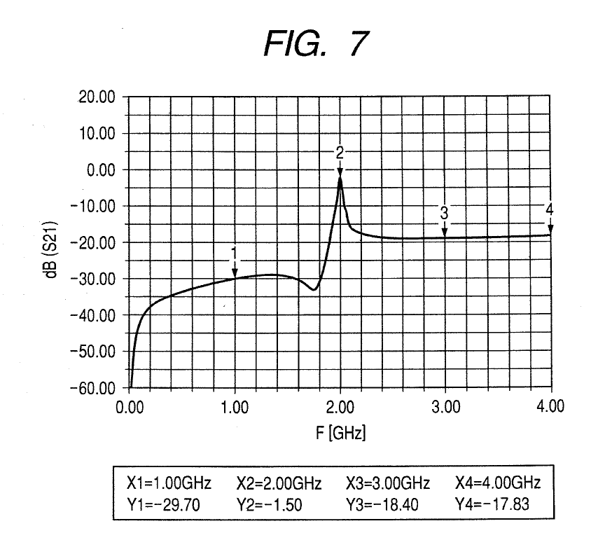

FIG. 7 is a diagram illustrating the result of a simulation in which filter characteristics was simulated depending on the circuit model shown in FIG. 6. As apparent from the result of the simulation, sharp filter characteristic was obtained.

### Fourth Alternative Embodiment

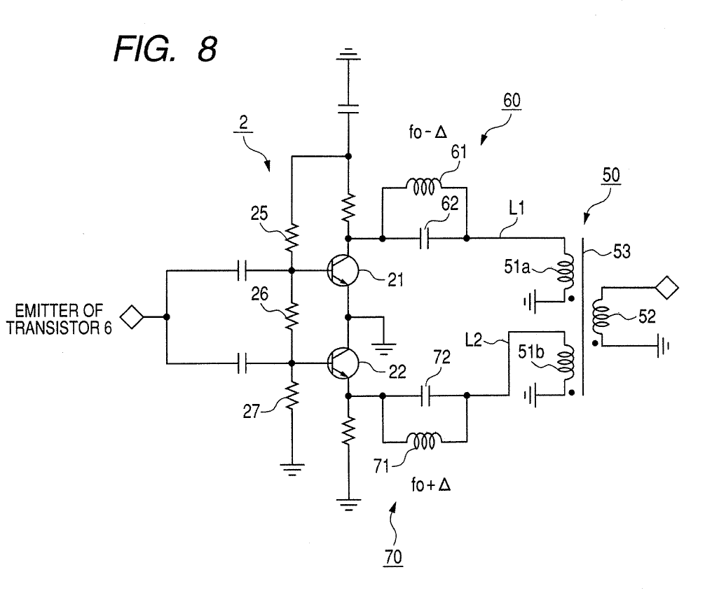

FIG. 8 is a diagram illustrating elements of a fourth alternative embodiment, which includes an output branching circuit 2 inverting a phase by using a cascade connection of transistors, trap circuits 60 and 70 composed of LC parallel resonance circuits, and a high-frequency transformer coupler 50.

For trap circuit 60, the trap frequency (fo−Δ) deviated from the center oscillation frequency (fo=2.0 GHz) to a lower band side by a small amount is established. In addition, for the trap circuit 70, the trap frequency (fo+Δ) deviated to a higher band side by a small amount is established.

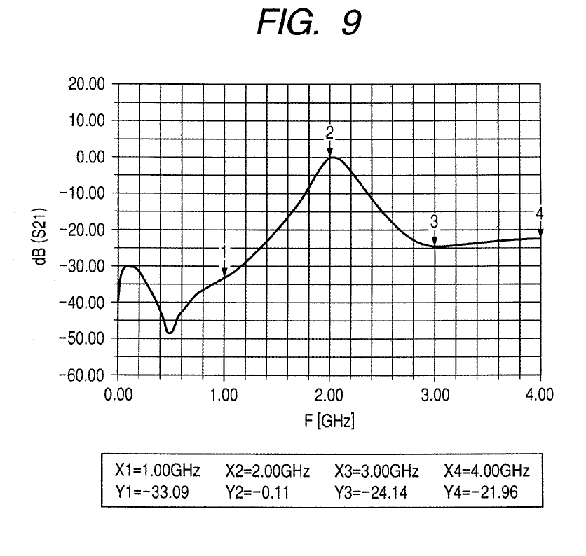

FIG. 9 is a diagram illustrating the result of a simulation in which filter characteristics was simulated depending on the circuit model shown in FIG. 8. As apparent from the result of the simulation, the rejection band was extended and widened from the oscillation frequency (2.0 GHz) to a lower passband and a higher passband.

### First Comparative Example 1

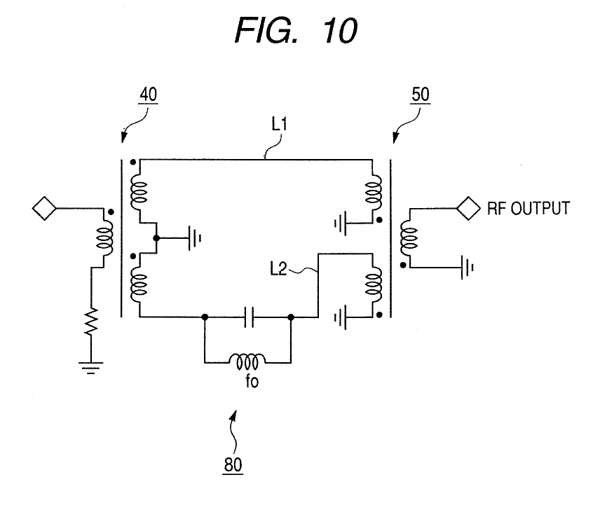

FIG. 10 is a diagram illustrating a comparative example in which the trap circuit 60 is removed from the first signal path L1 in FIG. 4, and a trap circuit 80 composed of a LC parallel resonance circuit in which the trap frequency is established as the oscillation frequency fo is provided in the second signal path L2.

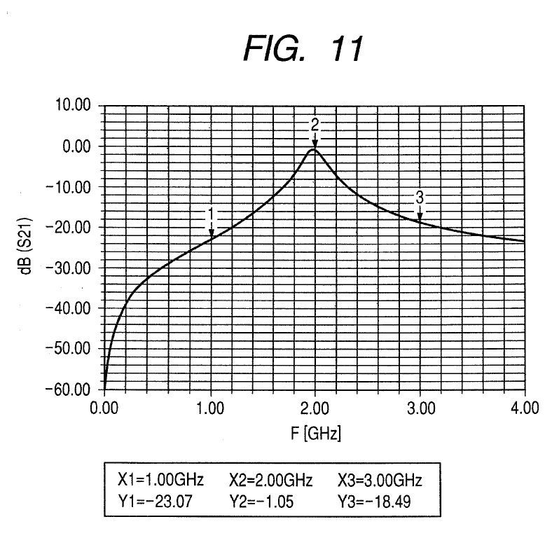

FIG. 11 is a diagram illustrating the result of a simulation in which filter characteristics of a first comparative example was simulated. As compared to the filter characteristics of the second alternative embodiment shown in FIG. 5, it is apparent that a gentle slope was obtained.

Further, the invention is not limited to the above-mentioned embodiments and alternative embodiments. For example, instead of a combination of the phase inversion amplifier and the trap circuit, a combination of a saturation type phase inversion amplifier and attenuation may be used.

The invention is equally applicable to a filter circuit in which noise is removed by phase-inverting one side of the branched high frequency signals and combining the signals.

It should be understood by those skilled in the art that various modifications, combinations, sub-combinations and alterations may occur depending on design requirements and other factors insofar as they are within the scope of the appended claims of the equivalents thereof.

What is claimed is:

1. A filter circuit comprising:
a phase inversion branching circuit branching an input signal and outputting separately first and second signals with mutually-inverted phases from first and second output terminals;
a first band rejection filter connected to the first output terminal of the phase inversion branching circuit and having a first rejection band;
a second band rejection filter connected to the second output terminal of the phase inversion branching circuit and having a second rejection band different from the first rejection band; and
a combiner combining the outputs of the first and second band rejection filters.

2. The filter circuit of claim 1, wherein the first and second band rejection filters are similar in circuit elements to each other and both have a different circuit constant.

3. The filter circuit of claim 1, wherein the phase inversion branching circuit further includes a branching circuit branching an input signal to first and second signals and outputting the first and second signals; and
a phase inverting circuit converting the first and second signals output from the branching circuit, to the signals with mutually-inverted phases, and
wherein the phase inverting circuit includes a first transistor in which a base is connected to the one output stage of the branching circuit, a collector is grounded in a high-frequency manner, and an emitter is the first output terminal; and a second transistor in which a base is connected to the other output stage of the branching circuit, a collector is the second output terminal, and an emitter is grounded in a high-frequency manner.

4. The filter circuit of claim 3, wherein the collector of the first transistor and the emitter of the second transistor are connected with each other and power source voltage is applied between the collector of the second transistor and the emitter of the first transistor.

5. The filter circuit of claim 1, wherein the first and second band rejection filters are parallel resonance circuits which are interposed respectively in series in respective signal lines where the first and second signals output from the first and second output terminals of the phase inversion branching circuit are propagated respectively.

6. The filter circuit of claim 1, wherein the first and second band rejection filters are serial resonance circuits which are provided between a ground and respective signal lines where the first and second signals output from the first and second output terminals of the phase inversion branching circuit are propagated respectively.

7. The filter circuit of claim 1, wherein the input signal is an oscillating signal of a voltage-controlled oscillating circuit.

8. A voltage-controlled oscillating circuit comprising:
an oscillation circuit unit controlling an oscillation frequency of an oscillating signal, depending on a voltage control signal applied from the outside;
a phase inversion branching circuit connected to the output stage of the oscillation circuit unit, and branching the oscillating signal and outputting separately a first and second signals with mutually-inverted phases from first and second output terminals;
a first band rejection filter connected to the first output terminal of the phase inversion branching circuit and having a first rejection band;
a second band rejection filter connected to the second output terminal of the phase inversion branching circuit and having a second rejection band different from the first rejection band; and
a combiner combining the outputs of the first and second band rejection filters,
the first and second band rejection filters respectively including resonance circuits which include an inductor and a variable capacitive element connected to the inductor and controlling capacitance by the voltage control signal.
